(19) United States
(12) Patent Application Publication
(10) Pub. No.: US 2023/0187482 A1
(43) Pub. Date: Jun. 15, 2023

(54) METHOD OF MANUFACTURING SEMICONDUCTOR STRUCTURE AND SEMICONDUCTOR STRUCTURE

(71) Applicant: CHANGXIN MEMORY TECHNOLOGIES, INC., Hefei City (CN)

(72) Inventors: Jun XIA, Hefei City (CN); Mingguang ZUO, Hefei City (CN); Shijie BAI, Hefei City (CN)

(21) Appl. No.: 17/660,461

(22) Filed: Apr. 25, 2022

(30) Foreign Application Priority Data
Dec. 13, 2021 (CN) 202111514833.6

(51) Int. Cl. H01L 49/02

(52) U.S. Cl. CPC H01L 28/92; H01L 27/10844

(57) ABSTRACT

The present disclosure provides a method of manufacturing a semiconductor structure and a semiconductor structure. The method of manufacturing a semiconductor structure includes: forming a first stacked structure, and forming a first target structure in the first stacked structure; and forming a second stacked structure on the first stacked structure, and forming a second target structure in contact with the first target structure in the second stacked structure.

### CROSS-REFERENCE TO RELATED APPLICATIONS

This application claims the priority of Chinese Patent Application No. 202111514833.6 submitted to the Chinese Intellectual Property Office on Dec. 13, 2021, the disclosure of which is incorporated herein in its entirety by reference.

### TECHNICAL FIELD

The present disclosure relates to the technical field of semiconductors, and in particular to a method of manufacturing a semiconductor structure and a semiconductor structure.

### BACKGROUND

With the increase in integration degree of semiconductor structures, capacitor structures are developed toward high aspect ratios and high densities. During manufacture of the capacitor structures, there are different etching rates for regions of different densities. In case of a high aspect ratio of the capacitor structure, manufacturing progresses may be varied for regions of different densities, and some regions are etched insufficiently, while other regions are etched excessively, thus affecting the product yield.

### SUMMARY

An overview of the subject matter detailed in the present disclosure is provided below, which is not intended to limit the protection scope of the claims.

The present disclosure provides a method of manufacturing a semiconductor structure and a semiconductor structure.

An aspect of the present disclosure provides a method of manufacturing a semiconductor structure, including: forming a first stacked structure, and forming a first target structure in the first stacked structure; and forming a second stacked structure on the first stacked structure, and forming a second target structure in contact with the first target structure in the second stacked structure.

Another aspect of the present disclosure provides a semiconductor structure, including:

a bottom electrode, including a first target structure and a second target structure stacked on the first target structure; and

a support structure, including an intermediate support layer covering a part of a seam of a connecting surface of the first target structure and the second target structure.

Other aspects of the present disclosure are understandable upon reading and understanding of the drawings and detailed description.

### BRIEF DESCRIPTION OF THE DRAWINGS

The drawings incorporated into the specification and constituting part of the specification illustrate the embodiments of the present disclosure, and are used together with the description to explain the principles of the embodiments of the present disclosure. In these drawings, similar reference numerals are used to represent similar elements. The drawings in the following description are part rather than all of the embodiments of the present disclosure. Those skilled in the art may derive other drawings based on these drawings without creative efforts.

FIG. 1 is a flowchart of a method of manufacturing a semiconductor structure according to an exemplary embodiment;

FIG. 2 is a flowchart for forming first target structures in a method of manufacturing a semiconductor structure according to an exemplary embodiment;

FIG. 3 is a flowchart for forming second target structures in a method of manufacturing a semiconductor structure according to an exemplary embodiment;

FIG. 4 is a flowchart of a method of manufacturing a semiconductor structure according to an exemplary embodiment;

FIG. 5 is a flowchart for removing a part of a second stacked structure and a part of a first stacked structure in a method of manufacturing a semiconductor structure according to an exemplary embodiment;

FIG. 6 is a flowchart of a method of manufacturing a semiconductor structure according to an exemplary embodiment;

FIG. 7 is a schematic diagram for forming a first stacked structure according to an exemplary embodiment;

FIG. 8 is a schematic diagram for patterning a first buffer layer according to an exemplary embodiment;

FIG. 9 is a schematic diagram for forming first target pattern holes according to an exemplary embodiment;

FIG. 10 is a schematic diagram of the first target pattern holes in FIG. 9;

FIG. 11 is a schematic diagram for forming a first conductive layer according to an exemplary embodiment;

FIG. 12 is a schematic diagram for forming first target structures according to an exemplary embodiment;

FIG. 13 is a schematic diagram for forming a first stacked structure according to an exemplary embodiment;

FIG. 14 is a schematic diagram for patterning a second buffer layer according to an exemplary embodiment;

FIG. 15 is a schematic diagram for forming second target pattern holes according to an exemplary embodiment;

FIG. 16 is a schematic diagram for forming a second conductive layer according to an exemplary embodiment;

FIG. 17 is a schematic diagram for forming second target structures according to an exemplary embodiment;

FIG. 18 is a schematic diagram for forming a first mask layer according to an exemplary embodiment;

FIG. 19 is a top view of FIG. 18.

FIG. 20 is a schematic diagram for removing a part of a third sacrificial layer according to an exemplary embodiment;

FIG. 21 is a schematic diagram for removing a second sacrificial layer according to an exemplary embodiment;

FIG. 22 is a schematic diagram for forming support structures according to an exemplary embodiment;

FIG. 23 is a schematic diagram for removing a part of a first sacrificial layer according to an exemplary embodiment;

FIG. 24 is a schematic diagram for forming a dielectric layer according to an exemplary embodiment;

FIG. 25 is a schematic diagram for forming a top electrode layer according to an exemplary embodiment;

FIG. 26 is a schematic diagram for completely removing a third sacrificial layer according to an exemplary embodiment;

FIG. 27 is a top view of FIG. 26.

FIG. 28 is a schematic diagram for forming a dielectric layer according to an exemplary embodiment; and

FIG. 29 is a schematic diagram for forming a top electrode layer according to an exemplary embodiment;

### REFERENCE NUMERALS

01. dense region, 02. non-dense region, 10. first stacked structure, 11. first sacrificial layer, 12. first support layer, 100. bottom electrode, 101. first target pattern hole, 110. first target structure, 111. first conductive layer, 120. second target structure, 121. second conductive layer, 20. second stacked structure, 21. second support layer, 22. dielectric layer, 200. support structure, 201. second target pattern hole, 210. support unit, 221. second sacrificial layer, 222. third sacrificial layer, 30. substrate, 300. upper support layer, 31. isolation layer, 40. capacitor contact portion, 400. dielectric layer, 50. first buffer layer, 51. first target pattern, 500. top electrode layer, 60. patterned layer, 70. second buffer layer, 71. second target pattern, 80. first mask layer, and 81. first pattern.

### DETAILED DESCRIPTION

To make the objectives, technical solutions, and advantages of the embodiments of the present disclosure clearer, the following clearly and completely describes the technical solutions in the embodiments of the present disclosure with reference to the accompanying drawings in the embodiments of the present disclosure. Apparently, the described embodiments are some but not all of the embodiments of the present disclosure. All other embodiments obtained by those skilled in the art based on the embodiments of the present disclosure without creative efforts should fall within the protection scope of the present disclosure. It should be noted that the embodiments in the present disclosure and features in the embodiments may be combined with each other in a non-conflicting manner.

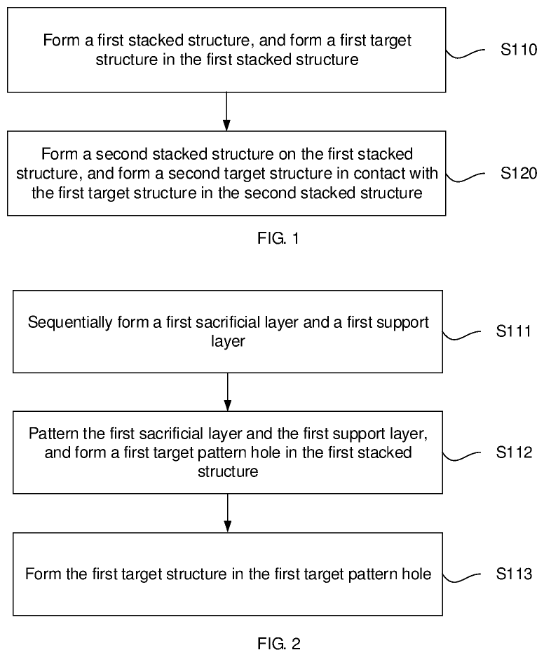

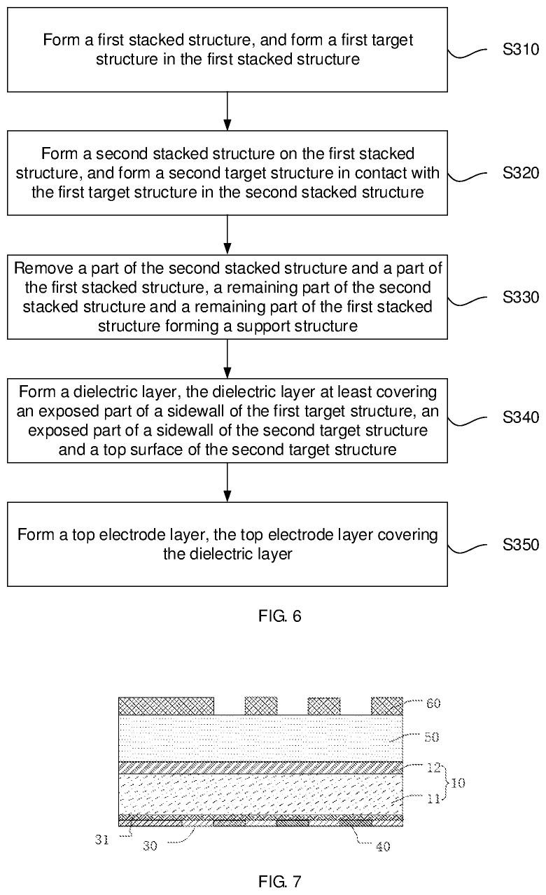

An exemplary embodiment of the present disclosure provides a method of manufacturing a semiconductor structure. FIG. 1 shows a flowchart of a method of manufacturing a semiconductor structure according to an exemplary embodiment of the present disclosure. FIG. 7 to FIG. 29 are schematic diagrams of various stages in a method of manufacturing a semiconductor structure. The method of manufacturing a semiconductor structure will be described below with reference to FIG. 7 to FIG. 29.

There are no limits made on the semiconductor structure in the embodiment. The semiconductor structure is described below by taking a dynamic random access memory (DRAM) as an example, but the embodiment is not limited thereto. The semiconductor structure in the embodiment may also be other structures.

As shown in FIG. 1, an exemplary embodiment of the present disclosure provides a method of manufacturing a semiconductor structure. The manufacturing method includes:

Step S110: Form a first stacked structure, and form a first target structure in the first stacked structure.

In the embodiment, as shown in FIG. 7, the first stacked structure 10 is formed on the substrate 30. The substrate is a semiconductor substrate, and includes a silicon-containing substance. The substrate 30 may be a silicon substrate, a silicon-germanium substrate or a silicon on insulator (SOI) substrate. In an example, referring to FIG. 7, an isolation layer 31 is provided on a top surface of the substrate 30.

As shown in FIG. 7, the substrate 30 includes a capacitor contact portion 40. The first stacked structure 10 is formed on the substrate 30. A part of the first stacked structure 10 is removed. As shown in FIG. 12, the first target structure 110 is formed in the first stacked structure 10. The first target structure 110 is in contact with the capacitor contact portion 40.

Step S120: Form a second stacked structure on the first stacked structure, and form a second target structure in contact with the first target structure in the second stacked structure.

As shown in FIG. 13, the second stacked structure 20 is formed. The second stacked structure 20 covers a top surface of the first stacked structure 10 and a top surface of the first target structure 110. As shown in FIG. 17, referring to FIG. 13, a part of the second stacked structure 20 is removed, and the second target structure 120 is formed in the second stacked structure 20. A bottom surface of the second target structure 120 at least covers a part of the top surface of the first target structure 110. The second target structure 120 is connected to the first target structure 110. Both the first target structure 110 and the second target structure 120 jointly serve as a target structure.

The manufacturing method in the embodiment separates the manufacture of the target structure into the manufacture of the first target structure and the manufacture of the second target structure, thereby reducing the depth in each manufacture and minimizing the influence of a high aspect ratio on the manufacture.

Descriptions will be made to the implementation of Step S110 in an exemplary embodiment. During implementation, as shown in FIG. 2, the forming a first stacked structure, and forming a first target structure in the first stacked structure includes:

Step S111: Sequentially form a first sacrificial layer and a first support layer.

As shown in FIG. 7, the first sacrificial layer 11 is formed on the substrate 30. The thickness of the first sacrificial layer 11 depends on the height of the first target structure 110 to be formed. The higher the first target structure 110 to be formed, the thicker the corresponding first sacrificial layer 11. The first support layer 12 is provided on the first sacrificial layer 11 to form the first stacked structure 10.

The first sacrificial layer 11 is made of a material including silicon oxide or boro-phospho-silicate glass (BPSG). The material of the first sacrificial layer 11 may be doped with boron or phosphorus. The first support layer 12 is made of a material including any one or a combination of silicon nitride, silicon oxynitride, or silicon carbonitride.

Step S112: Pattern the first sacrificial layer and the first support layer, and form a first target pattern hole in the first stacked structure.

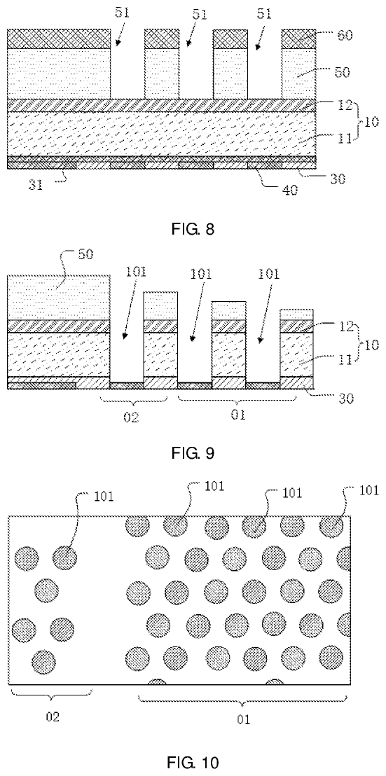

As shown in FIG. 7, a first buffer layer 50 is formed on the top surface of the first stacked structure 10. A patterned layer 60 is formed on the first buffer layer 50. The first buffer layer 50 may be made of a material including polycrystalline silicon. As shown in FIG. 8, the first buffer layer 50 is patterned according to the patterned layer 60 to form a first target pattern 51 in the first buffer layer 50. The first target pattern 51 may include a plurality of pattern regions having a same pattern density or different pattern densities. As shown in FIG. 9, with the patterned first buffer layer 50 as a mask, the first stacked structure 10 is etched to remove a part of the first support layer 12 and a part of the first sacrificial layer 11 exposed by the first target pattern 51 and transfer the first target pattern 51 to the first stacked structure 10. The first target pattern hole 101 is formed in the first stacked structure 10. The first target pattern hole 101 exposes the capacitor contact portion 40 in the substrate 30.

In the embodiment, the first target pattern 51 is formed according to a distribution density of the capacitor contact portion 40 in the substrate 30. The first target pattern 51 is distributed in a dense region 01 and a non-dense region 02. As shown in FIG. 9 and FIG. 10, a plurality of the first target pattern holes 101 formed according to the first target pattern 51 are partially formed into the dense region 01 and partially formed into the non-dense region 02 in the embodiment.

In the embodiment, as shown in FIG. 9, when the first stacked structure 10 is etched with the first buffer layer 50 as the mask, a part of the first buffer layer 50 on a top of the dense region 01 is etched more fast than a part of the first buffer layer 50 on a top of the non-dense region 02 due to the higher pattern density of the dense region 01. The embodiment reduces the depth of the first target structure 110 in the manufacture, shortens the time for forming the first target structure 110, and ensures that after the first target pattern hole 101 is formed in the non-dense region 02, the part of the first buffer layer 50 on the top of the dense region 01 is still sufficiently thick to prevent the etching damage to the top of the first stacked structure 10.

Step S113: Form the first target structure in the first target pattern hole.

As shown in FIG. 12, a conductive material is deposited in the first target pattern hole 101 and the first target structure 110 is formed. A top surface of the first target structure 110 is not higher than a top surface of the first support layer 12. A bottom surface of the first target structure 110 is in contact with the capacitor contact portion 40.

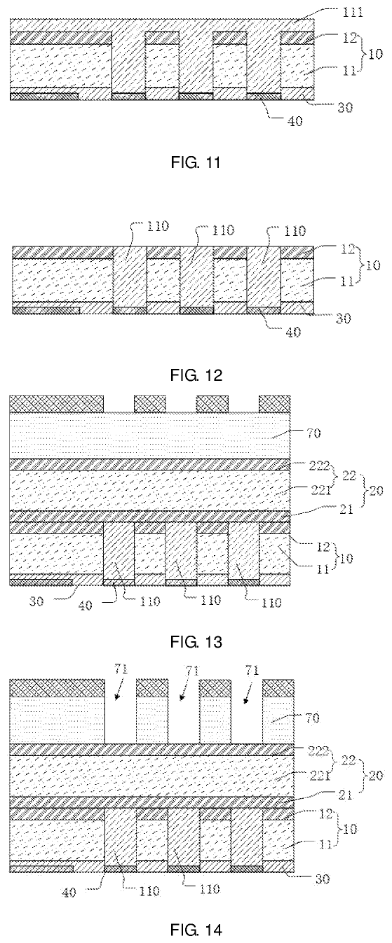

As shown in FIG. 11, the conductive material may be deposited with atomic layer deposition (ALD) to fill the first target pattern hole 101 and cover the top surface of the first stacked structure 10, thus forming a first conductive layer 111. As shown in FIG. 12, the first conductive layer 111 covering the top surface of the first stacked structure 10 is etched back and removed to form the first target structure 110. The first target structure 110 is made of a material including a compound formed from one or both of a metal nitride or a metal silicide, such as titanium nitride, titanium silicide, titanium silicide, TiSiₓN_{y}, etc.

By shortening the time for forming the first target pattern hole, the top surface of the first stacked structure is still protected by the first buffer layer after the first target pattern hole is formed. The method in the embodiment prevents the etching damage to the top of the first target pattern hole in the dense region due to the greater etching rate of the dense region than that of the non-dense region, and ensures the highly accurate size of the first target structure.

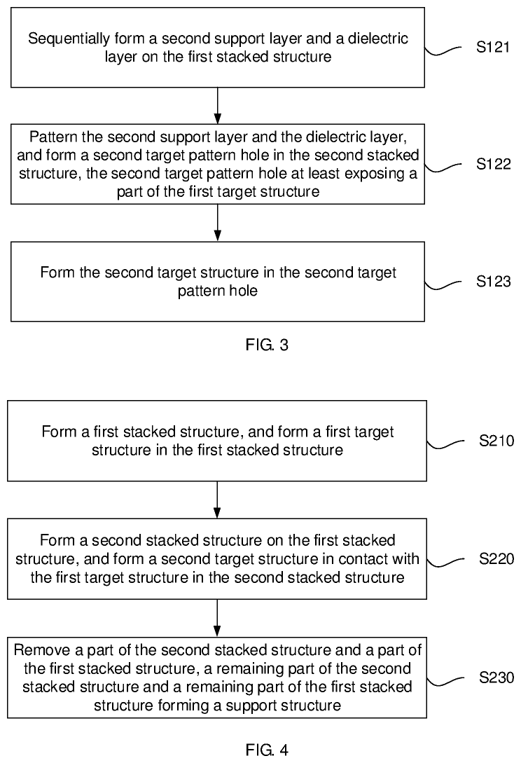

Descriptions will be made to the implementation of Step S120 in an exemplary embodiment. During implementation, as shown in FIG. 3, the forming a second stacked structure, and forming a second target structure in the second stacked structure includes:

Step S121: Sequentially form a second support layer and a dielectric layer on the first stacked structure.

As shown in FIG. 13, the second support layer 21 is formed on the first stacked structure 10. The second support layer 21 covers the top surface of the first support layer 12 and the top surface of the first target structure 110. The dielectric layer 22 is formed on the second support layer 21.

The second support layer 21 is made of a material including any one or a combination of silicon nitride, silicon oxynitride, or silicon carbonitride.

In the embodiment, as shown in FIG. 13, when the dielectric layer 22 is formed, a second sacrificial layer 221 is formed on the second support layer 21. The thickness of the second sacrificial layer 221 depends on the height of the second target structure 120 to be formed. The higher the second target structure 120 to be formed, the thicker the corresponding second sacrificial layer 221. A third sacrificial layer 222 is formed on the second sacrificial layer 221.

Both the third sacrificial layer 222 and the second sacrificial layer 221 are made of a material with an etch selectivity. Exemplarily, the second sacrificial layer 221 may be made of a material including silicon oxide or BPSG. The material of the second sacrificial layer 222 may be doped with boron or phosphorus. The third sacrificial layer may be made of a material including any one or a combination of silicon nitride, silicon oxynitride, or silicon carbonitride.

Step S122: Pattern the second support layer and the dielectric layer, and form a second target pattern hole in the second stacked structure, the second target pattern hole at least exposing a part of the first target structure.

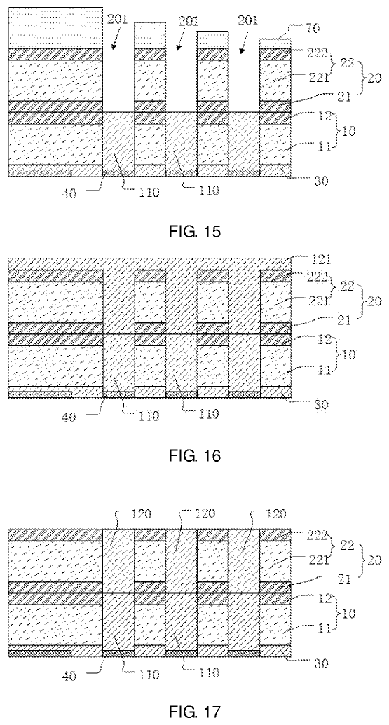

As shown in FIG. 13, a second buffer layer 70 is formed on the top surface of the second stacked structure 20. As shown in FIG. 14, the second buffer layer 70 is patterned to form a second target pattern 71. As shown in FIG. 15, with the second buffer layer 70 as a mask, the second stacked structure 20 is etched to remove a part of the third sacrificial layer 222, a part of the second sacrificial layer 221 and a part of the second support layer 21, and transfer the second target pattern 71 to the second stacked structure 20. The second target pattern hole 201 is formed in the second stacked structure 20. The second target pattern hole 201 at least exposes a part of the top surface of the first target structure 110. The second buffer layer 70 may be made of a material including polycrystalline silicon.

In the embodiment, the second target pattern holes 201 are arranged in a same manner as the first target pattern holes 101. The second target pattern holes 201 are partially formed in the dense region 01, and partially formed in the non-dense region 02.

Likewise, referring to FIG. 15, by reducing the depth of the second target pattern hole 201 in the manufacture, the embodiment shortens the time for forming the second target pattern hole 201, ensures that after the second target pattern hole 201 is formed in the non-dense region 02, a part of the second buffer layer 70 on the top of the dense region 01 is still sufficiently thick to prevent the etching damage to the top of the second target pattern hole 201, and has the highly accurate size of the second target pattern hole 201.

Step S123: Form the second target structure in the second target pattern hole.

As shown in FIG. 17, a conductive material is deposited in the second target pattern hole 201 and the second target structure 120 is formed. The second target structure covers the part of the first target structure exposed.

As shown in FIG. 16, the conductive material may be deposited with the ALD to fill the second target pattern hole 201 and cover the top surface of the second stacked structure 20, thus forming a second conductive layer 121. As shown in FIG. 17, the second conductive layer 121 covering the top surface of the second stacked structure 20 is etched back and removed to form the second target structure 120. The second target structure 120 is made of a material including a compound formed from one or both of a metal nitride or a metal silicide, such as titanium nitride, titanium silicide, titanium silicide, TiSiₓN_{y}, etc. The second target structure 120 and the first target structure 110 may be made of a same material or different materials.

The embodiment reduces the depth in each manufacture to ensure the yield of the first target structure and the second target structure, thereby improving the yield of the final semiconductor structure.

As shown in FIG. 4, an exemplary embodiment of the present disclosure provides a method of manufacturing a semiconductor structure, including:

Step S210: Form a first stacked structure, and form a first target structure in the first stacked structure.

Step S220: Form a second stacked structure on the first stacked structure, and form a second target structure in contact with the first target structure in the second stacked structure.

Step S230: Remove a part of the second stacked structure and a part of the first stacked structure, a remaining part of the second stacked structure and a remaining part of the first stacked structure forming a support structure.

Steps S210-S220 in the embodiment are implemented in a same manner as Steps S110-S220 of the foregoing embodiment, and will not be repeated herein.

In the embodiment, as shown in FIG. 5, the removing a part of the second stacked structure and a part of the first stacked structure includes:

Step S231: Form a first mask layer, the first mask layer covering a part of a top surface of the second stacked structure and a part of a top surface of the second target structure.

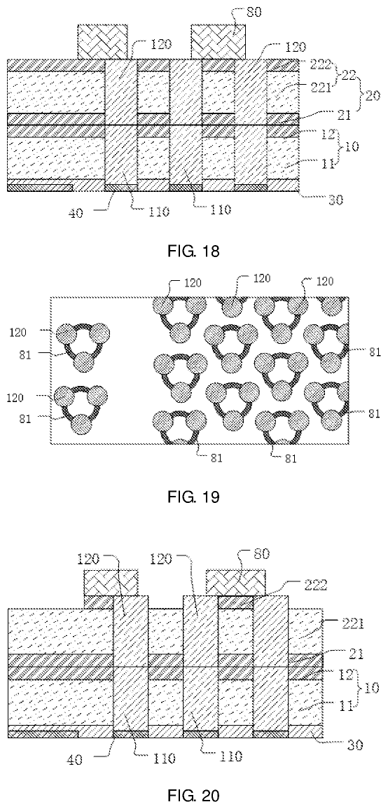

As shown in FIG. 18 and FIG. 19, referring to FIG. 17, the first mask layer 80 is provided with a plurality of first patterns 81 on the top surfaces of the second target structures 120. The plurality of first patterns 81 are provided according to the positions and distribution densities of the second target structures 120. The first patterns 81 each cover at least a part of a top surface of one second stacked structure 20.

Step S232: Sequentially remove a part of the third sacrificial layer, the second sacrificial layer and a part of the second support layer of the second stacked structure based on the first mask layer.

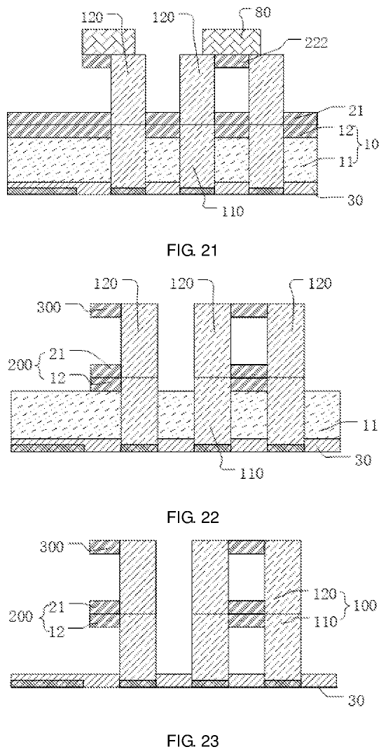

As shown in FIG. 20, with the first mask layer 80 as a mask, a part of the third sacrificial layer 222 exposed by the first mask layer 80 is removed with dry etching or wet etching to expose the second sacrificial layer 221. As shown in FIG. 21, the second sacrificial layer 221 is removed completely by an acid solution with the wet etching to expose the second support layer 21. As shown in FIG. 22, a part of the second support layer 21 exposed by the first mask layer 80 is removed with the dry etching or the wet etching to transfer the first patterns 81 to the first stacked structure 10.

Step S233: Sequentially remove a part of the first support layer and the first sacrificial layer of the first stacked structure based on the first mask layer.

As shown in FIG. 22, a part of the first support layer 12 exposed by the first mask layer 80 is removed with the dry etching or the wet etching to expose the first sacrificial layer 11. As shown in FIG. 23, the first sacrificial layer 11 is removed completely by an acid solution with the wet etching.

As shown in FIG. 23, the second target structure 120 is stacked on the first target structure 110. The first target structure 110 and the second target structure 120 form the target structure, and a remaining part of the first support layer 12 and a remaining part of the second support layer 21 form a support structure 200. The support structure 200 at least covers a part of a seam of the first target structure 110 and the second target structure 120.

In the embodiment, a remaining part of the third sacrificial layer 222 forms an upper support layer 300. The upper support layer 300 is provided on a top of the second target structure 120 and covers a part of a sidewall of the second target structure 120. The upper support layer 300 keeps the same shape as the support structure 200. The upper support layer 300 and the support structure 200 jointly support the target structure formed by the first target structure 110 and the second target structure 120. When the target structure is high, the upper support layer 300 can better support the target structure, thus ensuring the stability and the anti-tipping performance of the semiconductor structure.

According to the semiconductor structure in the embodiment, the support structure is provided at a junction of the first target structure and the second target structure to implement stable connection between the first target structure and the second target structure.

According to an exemplary embodiment, as shown in FIG. 19, when the first mask layer 80 is formed, a plurality of adjacent second target structures 120 serve as one group and a first pattern 81 is correspondingly formed on top surfaces of the second target structures in each group. The first pattern 81 exposes a part of each second target structure 120 in each group.

According to the semiconductor structure in the embodiment, the first target structure and the second target structure are stacked to form the target structure. A plurality of the target structures serve as one group, and the plurality of the target structures in each group are connected into a whole through the support structure, such that the anti-tipping performance of the semiconductor structure and the stability of the semiconductor structure are improved.

In an embodiment, as shown in FIG. 19, when the first mask layer 80 is formed, three adjacent second target structures 120 serve as one group. The first pattern 81 is an annular pattern on top surfaces of the second target structures in each group. The first pattern 81 covers a part of the top surface of each second target structure 120 in the group and a part of the top surface of the surrounding third sacrificial layer 222.

The support structure formed based on the first mask layer in the embodiment includes three independent target structures. The three target structures in each group are connected into a whole through the support structure. Any two of the three target structures in each group are connected by a support unit. Therefore, the space occupied by the support structure in the semiconductor structure is reduced and the available space in the semiconductor is increased.

In the embodiment, the first mask layer exposes a larger area of the third sacrificial layer and the window for removing the third sacrificial layer exposed by the first mask layer is larger, such that the third sacrificial layer is removed more easily. Likewise, other parts of the second stacked structure and the first stacked structure are also removed more easily.

In other embodiments, as shown in FIG. 5, the removing a part of the second stacked structure and a part of the first stacked structure further includes:

Step S234: Remove the remaining part of the third sacrificial layer.

In the embodiment, as shown in FIG. 26, the third sacrificial layer is removed completely with the dry etching or the wet etching. The semiconductor structure formed herein does not include the upper support layer, such that the space occupied by the upper support layer in the semiconductor structure is omitted and the available space in the semiconductor structure is increased. Moreover, without the third sacrificial layer, larger side of the second target structure is exposed. When the target structure formed in the embodiment serves as the bottom electrode, the bottom electrode has larger contact area to further improve the electrical performance of the capacitor structure.

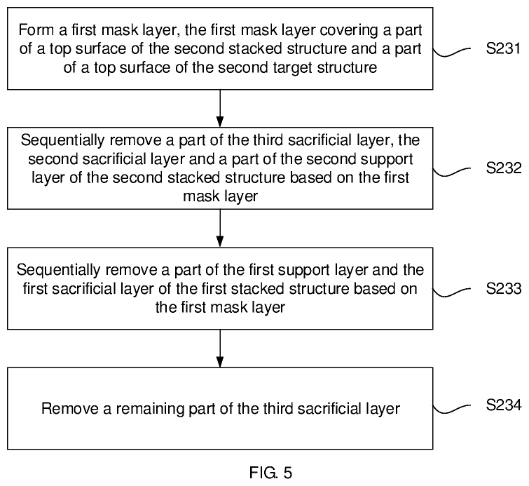

As shown in FIG. 6, an exemplary embodiment of the present disclosure provides a method of manufacturing a semiconductor structure, including:

Step S310: Form a first stacked structure, and form a first target structure in the first stacked structure.

Step S320: Form a second stacked structure on the first stacked structure, and form a second target structure in contact with the first target structure in the second stacked structure.

Step S330: Remove a part of the second stacked structure and a part of the first stacked structure, a remaining part of the second stacked structure and a remaining part of the first stacked structure forming a support structure.

Steps S310-S330 of the embodiment are implemented in the same manner as Steps S210-S230 of the foregoing embodiment, and will not be repeated herein.

Step S340: Form a dielectric layer, the dielectric layer at least covering an exposed part of a sidewall of the first target structure, an exposed part of a sidewall of the second target structure and a top surface of the second target structure.

The dielectric layer 400 may be deposited with ALD. The dielectric layer 400 is made of a high-k material, which has a dielectric constant greater than that of silicon dioxide.

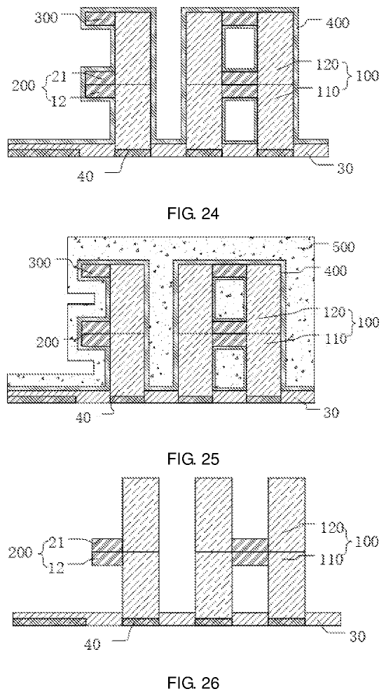

As shown in FIG. 24, the dielectric layer 400 covers the exposed part of the sidewall of the first target structure 110, the exposed part of the sidewall of the second target structure 120, the top surface of the second target structure 120, and the support structure 200. When the semiconductor structure includes the upper support layer 300, the dielectric layer 400 further covers the upper support layer 300.

In the embodiment, the high-k material may include a compound containing one or more of rare earth elements, Hf, Rh, Ba or Al. The high-k material can be hafnium (IV) oxide, titanium nitride, aluminium oxide, lanthanum oxide, etc.

Step S350: Form a top electrode layer, the top electrode layer covering the dielectric layer.

As shown in FIG. 25, referring to FIG. 24, the top electrode layer 500 may be deposited with the ALD. The top electrode layer 500 is made of a material including a compound formed from one or both of a metal nitride or a metal silicide. In the embodiment, the top electrode layer 500 may include one or two of titanium nitride, titanium silicide, titanium silicide, or TiSiₓN_{y}.

In the embodiment, as shown in FIG. 25 or FIG. 29, with the stacked first target structure 110 and second target structure 120 as the bottom electrode 100, the dielectric layer 400 and the top electrode layer 500 are sequentially formed on the bottom electrode 100. The bottom electrode 100, the dielectric layer 400 and the top electrode layer 500 are formed into a capacitor structure.

The capacitor structure formed in the embodiment takes the superposed first target structure and second target structure as the bottom electrode. The bottom electrode is formed in two manufacturing steps, such that the first target structure and second target structure of the bottom electrode have the highly accurate sizes and the bottom electrode has the highly accurate size. Even if the capacitor structure having a high aspect ratio is formed, the capacitor structure can still keep the highly accurate size to achieve the better performance and higher yield of the semiconductor structure.

An exemplary embodiment of the present disclosure provides a semiconductor structure. As shown in FIG. 23 and FIG. 26, the semiconductor structure includes: a bottom electrode 100 and a support structure 200. The bottom electrode 100 includes a first target structure 110, a second target structure 120 stacked on the first target structure 110, and the support structure 200. The support structure 200 covers a part of a seam of a connecting surface of the first target structure 110 and the second target structure 120.

According to the semiconductor structure in the embodiment, along a stacked direction, the first target structure 110 may be a structure having a same size from the bottom up, the first target structure 110 may be a structure having a size gradually increased from the bottom up.

The second target structure 120 may be a structure having a same size from the bottom up, a structure having a size gradually increased from the bottom up.

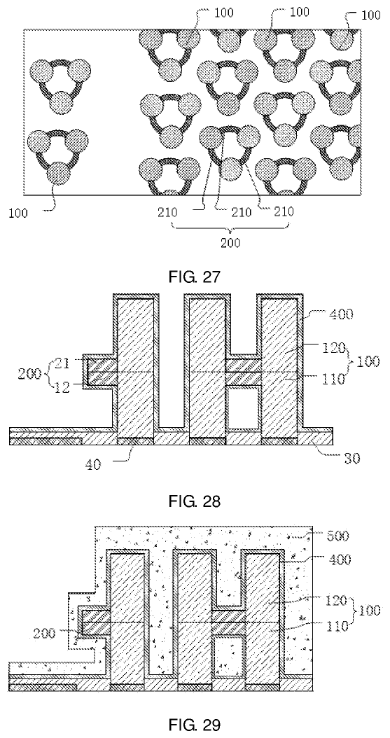

As shown in FIG. 26 and FIG. 27, the semiconductor structure in the embodiment includes a plurality of the bottom electrodes 100 and a plurality of the support structures 200. One or more bottom electrodes 100 serve as one group. The bottom electrodes 100 in each group are connected into a whole through one support structure 200. As each bottom electrode 100 can be connected to the support structure 200, the bottom electrode 100 in the semiconductor structure is more stable with the better anti-tipping performance.

According to an exemplary embodiment, most contents are substantially the same as the foregoing embodiment. The difference between the embodiment and the foregoing embodiment lies in: A projection pattern of each of the support structures 200 on the substrate includes a plurality of arc-shaped structures with a same radian.

As shown in FIG. 27, the support structures 200 each include a plurality of arc-shaped support units 210. Projection of the plurality of support units 210 on the substrate is located on a same circle. The support units 210 each are connected to seams of first target structures 110 and second target structures 120 of two adjacent bottom electrodes 100.

In the embodiment, the support structures 200 each are connected to three bottom electrodes 100. The support structures 200 each include three support units 210 with a same radian. Through the three support units 210, the three bottom electrodes 100 are sequentially connected into a whole. Connecting lines between central points of the three bottom electrodes 100 form an inscribed triangle of a circle where projection of the support units 210 on the substrate 30 is located. The semiconductor structure in the embodiment achieves the best anti-tipping performance and highest overall stability.

According to an exemplary embodiment, as shown in FIG. 23, the semiconductor structure further includes: an upper support layer 300, provided on a top of the second target structure 120 and covering a part of a sidewall of the second target structure 120. The upper support layer 300 is the same as the support structure 200 in shape.

In the embodiment, the upper support layer 300 is provided on the top of the semiconductor structure. When the semiconductor structure has a high aspect ratio, the upper support layer 300 better supports the top of the semiconductor structure, thereby achieving the better stability and anti-tipping performance of the semiconductor structure.

According to an exemplary embodiment, as shown in FIG. 25 and FIG. 29, the semiconductor structure further includes: a dielectric layer 400 and a top electrode layer 500. The dielectric layer 400 at least covers an exposed part of a sidewall of the first target structure 110, an exposed part of a sidewall of the second target structure 120, a top surface of the second target structure 120, and the support structure 200. When the semiconductor structure includes the top electrode layer 500, the dielectric layer 400 further covers the upper support layer 300. The top electrode layer 500 covers the dielectric layer 400.

According to an exemplary embodiment, as shown in FIG. 25 and FIG. 29, the semiconductor structure further includes: a substrate 30. The substrate 30 includes a capacitor contact portion 40. The first target structure 110 is provided on the capacitor contact portion 40. The first target structure 110 is in contact with the capacitor contact portion 40.

According to the semiconductor structure in the embodiment, the bottom electrode 100 includes the first target structure 110 and the second target structure 120, such that the bottom electrode is formed more easily. The support structure 200 is provided at a junction of the first target structure 110 and the second target structure 120 to implement stable connection between the first target structure 110 and the second target structure 120.

The embodiments or implementations of this specification are described in a progressive manner, and each embodiment focuses on differences from other embodiments. The same or similar parts between the embodiments may refer to each other.

In the description of the specification, the description with reference to terms such as “an embodiment”, “an illustrative embodiment”, “some implementations”, “an illustrative implementation” and “an example” means that the specific feature, structure, material or feature described in combination with the implementation(s) or example(s) is included in at least one implementation or example of the present disclosure.

In this specification, the schematic expression of the above terms does not necessarily refer to the same embodiment or example. Moreover, the described specific feature, structure, material or characteristic may be combined in an appropriate manner in any one or more embodiments or examples.

It should be noted that in the description of the present disclosure, the terms such as “center”, “top”, “bottom”, “left”, “right”, “vertical”, “horizontal”, “inner” and “outer” indicate the orientation or position relationships based on the drawings. These terms are merely intended to facilitate description of the present disclosure and simplify the description, rather than to indicate or imply that the mentioned device or element must have a specific orientation and must be constructed and operated in a specific orientation. Therefore, these terms should not be construed as a limitation to the present disclosure.

It can be understood that the terms such as “first” and “second” used in the present disclosure can be used to describe various structures, but these structures are not limited by these terms. Instead, these terms are merely intended to distinguish one element from another.

The same elements in one or more drawings are denoted by similar reference numerals. For the sake of clarity, various parts in the drawings are not drawn to scale. In addition, some well-known parts may not be shown. For the sake of brevity, the structure obtained by implementing a plurality of steps may be shown in one figure. In order to make the understanding of the present disclosure more clearly, many specific details of the present disclosure, such as the structure, material, size, processing process and technology of the device, are described below. However, as those skilled in the art can understand, the present disclosure may not be implemented according to these specific details.

Finally, it should be noted that the above embodiments are merely intended to explain the technical solutions of the present disclosure, rather than to limit the present disclosure. Although the present disclosure is described in detail with reference to the above embodiments, those skilled in the art should understand that they may still modify the technical solutions described in the above embodiments, or make equivalent substitutions of some or all of the technical features recorded therein, without deviating the essence of the corresponding technical solutions from the scope of the technical solutions of the embodiments of the present disclosure.

1. A method of manufacturing a semiconductor structure, comprising: forming a first stacked structure, and forming a first target structure in the first stacked structure; and forming a second stacked structure on the first stacked structure, and forming a second target structure in contact with the first target structure in the second stacked structure.

2. The method of manufacturing a semiconductor structure according to claim 1, wherein the forming a first stacked structure, and forming a first target structure in the first stacked structure comprises:
sequentially forming a first sacrificial layer and a first support layer;
patterning the first sacrificial layer and the first support layer, and forming a first target pattern hole in the first stacked structure; and
forming the first target structure in the first target pattern hole.

3. The method of manufacturing a semiconductor structure according to claim 2, wherein the forming the first target structure in the first target pattern hole comprises:
depositing a conductive material in the first target pattern hole and forming the first target structure, a top surface of the first target structure being not higher than a top surface of the first support layer.

4. The method of manufacturing a semiconductor structure according to claim 3, wherein the depositing a conductive material in the first target pattern hole and forming the first target structure comprises:
depositing the conductive material to fill the first target pattern hole and cover a top surface of the first stacked structure, and forming a first conductive layer; and
etching back and removing a part of the first conductive layer covering the top surface of the first stacked structure, and forming the first target structure.

5. The method of manufacturing a semiconductor structure according to claim 3, wherein a material of the first target structure is a compound formed from one or both of a metal nitride or a metal silicide.

6. The method of manufacturing a semiconductor structure according to claim 2, wherein the forming a second stacked structure, and forming a second target structure in the second stacked structure comprises:
sequentially forming a second support layer and a dielectric layer on the first stacked structure;
patterning the second support layer and the dielectric layer, and forming a second target pattern hole in the second stacked structure, the second target pattern hole at least exposing a part of the first target structure; and
forming the second target structure in the second target pattern hole.

7. The method of manufacturing a semiconductor structure according to claim 6, wherein the forming a dielectric layer comprises:
forming a second sacrificial layer on the second support layer, and forming a third sacrificial layer on the second sacrificial layer.

8. The method of manufacturing a semiconductor structure according to claim 6, wherein the forming the second target structure in the second target pattern hole comprises:
depositing a conductive material in the second target pattern hole and forming the second target structure, the second target structure covering the part of the first target structure exposed.

9. The method of manufacturing a semiconductor structure according to claim 8, wherein the depositing a conductive material in the second target pattern hole and forming the second target structure comprises:
depositing the conductive material to fill the second target pattern hole and cover a top surface of the second stacked structure, and forming a second conductive layer; and
etching back and removing a part of the second conductive layer covering the top surface of the second stacked structure, and forming the second target structure.

10. The method of manufacturing a semiconductor structure according to claim 8, wherein a material of the second target structure is a compound formed from one or both of a metal nitride or a metal silicide.

11. The method of manufacturing a semiconductor structure according to claim 1, wherein a material of the first target structure is the same as a material of the second target structure, or the material of the first target structure is different with the material of the second target structure.

12. The method of manufacturing a semiconductor structure according to claim 7, further comprising:
removing a part of the second stacked structure and a part of the first stacked structure, a remaining part of the second stacked structure and a remaining part of the first stacked structure forming a support structure.

13. The method of manufacturing a semiconductor structure according to claim 12, wherein the removing a part of the second stacked structure and a part of the first stacked structure comprises:
forming a first mask layer, the first mask layer covering a part of a top surface of the second stacked structure and a part of a top surface of the second target structure;
sequentially removing a part of the third sacrificial layer, the second sacrificial layer and a part of the second support layer of the second stacked structure based on the first mask layer; and
sequentially removing a part of the first support layer and the first sacrificial layer of the first stacked structure based on the first mask layer, wherein
a remaining part of the first support layer and a remaining part of the second support layer form the support structure.

14. The method of manufacturing a semiconductor structure according to claim 1, comprising:
providing a substrate, the substrate comprising a capacitor contact portion, wherein
the first stacked structure is formed on the substrate.

15. The method of manufacturing a semiconductor structure according to claim 14, wherein the forming a first target structure in the first stacked structure comprises:
forming the first target structure, the first target structure being in contact with the capacitor contact portion.

16. The method of manufacturing a semiconductor structure according to claim 1, further comprising:
forming a dielectric layer, the dielectric layer at least covering an exposed part of a sidewall of the first target structure, an exposed part of a sidewall of the second target structure and a top surface of the second target structure; and
forming a top electrode layer, the top electrode layer covering the dielectric layer.

17. A semiconductor structure, comprising:
a bottom electrode, comprising a first target structure and a second target structure stacked on the first target structure; and
a support structure, covering a part of a seam of a connecting surface of the first target structure and the second target structure.

18. The semiconductor structure according to claim 17, further comprising:
an upper support layer, provided on a top of the second target structure and covering a part of a sidewall of the second target structure.

19. The semiconductor structure according to claim 17, further comprising:
a dielectric layer, at least covering an exposed part of a sidewall of the first target structure, an exposed part of a sidewall of the second target structure, a top surface of the second target structure and the support structure; and
a top electrode layer, covering the dielectric layer.

20. The semiconductor structure according to claim 17, further comprising:
a substrate, comprising a capacitor contact portion, wherein
the first target structure is provided on the capacitor contact portion, and the first target structure is in contact with the capacitor contact portion.
